(19) United States
(12) Patent Application Publication
(10) Pub. No.: US 2019/0391782 A1
(43) Pub. Date: Dec. 26, 2019

(54) METHOD AND SYSTEM OF PROCESSING AN AUDIO RECORDING FOR FACILITATING PRODUCTION OF COMPETITIVELY LOUD MASTERED AUDIO RECORDING

(71) Applicant: Cary Randolph Miller, Gilbert, AZ (US)

(72) Inventor: Cary Randolph Miller, Gilbert, AZ (US)

(21) Appl. No.: 16/485,399

(22) PCT Filed: Feb. 13, 2018
(86) PCT No.: PCT/IB2018/050859

§ 371 Date: Aug. 12, 2019

Related U.S. Application Data
(60) Provisional application No. 62/457,723, filed on Feb. 10, 2017.

(51) Int. Cl. G06F 3/16; H03G 9/18; H03F 3/187; H03G 3/18; G06F 16/60; H03G 5/16

(52) U.S. Cl. CPC G06F 3/162; H03G 9/18; H03F 3/187; H04R 2430/01; G06F 16/60; H03G 5/165; H03G 3/18

(57) ABSTRACT

Disclosed is a method of processing an audio recording for facilitating production of competitively loud mastered audio recording with reduced distortion. The method includes receiving an audio file comprising the audio. Further, the method includes providing a first attenuation to the audio recording to produce a first attenuated audio recording and routing the first attenuated audio recording onto an input of a first bus. Further, the method includes providing a second attenuation to the first attenuated audio recording available to generate a second attenuated audio recording and routing the second attenuated audio recording onto an input of a second bus. Further, the method includes providing a third attenuation to the second attenuated audio recording to generate a third attenuated audio recording. Yet further, the method includes processing the third attenuated audio recording to generate a track output. Moreover, the method includes transmitting the track output to the electronic device.

The current application is a 371 of international Patent Cooperation Treaty (PCT) application PCT/IB2018/050859 filed on Feb. 12, 2018 while Feb. 10, 2018 was on a weekend. The PCT application PCT/IB2018/050859 claims a priority to the U.S. Provisional Patent application Ser. No. 62/457,723 filed on Feb. 10, 2017. The current application is filed on Aug. 12, 2019 while Aug. 10, 2019 was on a weekend.

### FIELD OF THE INVENTION

The present invention relates generally to audio recording. In particular, the present invention relates to a method and a system of processing an audio recording for facilitating production of competitively loud mastered audio recording with reduced distortion.

### BACKGROUND OF THE INVENTION

The “Loudness War” or “Loudness Race” are names commonly used to describe the tendency for major record labels (music companies) to increase the volume of mastered music recordings. This trend began in the 1990s, in parallel to the rising popularity of the CD as a storage medium. Major record labels had discovered through advertisers who employed focus groups, that an average listener's echoic (auditory) memory was far less reliable than their visual memory in contrast. Therefore, the louder a produced song became after being mastered (finalized), the more memorable the experience proved to be for the listener. This was considered commonplace and was widely believed to improve sales and media consumption, ultimately resulting in a technical race for audio engineers to increase the volume of audio recordings competitively.

Additionally, archiving digital music recordings is far less expensive and easier to maintain than analog music recordings. While the musical quality of mastered audio recordings has typically decreased in relation, the convenience of manipulating digital files for the listening public was too enticing for major record labels to ignore.

However, this method of commanding an audience's attention may lead to creation of considerable digital distortions by “clipping” (exceeding) digital zero. By increasing the volume so aggressively, the audio engineers had effectively reduced the dynamic range (headroom before distortion) to unmusical levels for the vast majority of mainstream music releases at the behest of major record labels, resulting in decades of heavily degraded audio being marketed to the public.

Further, digital distortion is always square wave, therefore, it will produce highly unpleasant sounds which are unnatural to the human ear, even to the point of potentially causing ear damage over long periods of time at loud volumes. While this does not take away from the effectiveness of increasing the sound in terms of listener engagement, it does result in a relatively low-quality final product.

Accordingly, there is a need for improved systems and methods of manipulating audio recordings during production which eliminate digital distortions without sacrificing any ability to create competitively loud mastered audio recordings that may also overcome one or more of the abovementioned problems and/or limitations.

### SUMMARY OF THE INVENTION

This summary is provided to introduce a selection of concepts in a simplified form that are further described below in the Detailed Description. This summary is not intended to identify key features or essential features of the claimed subject matter. Nor is this summary intended to be used to limit the claimed subject matter's scope.

Disclosed is a method of processing an audio recording for facilitating production of competitively loud mastered audio recording with reduced distortion. The method includes receiving, using a communication device, an audio file comprising the audio recording from an electronic device. Further, the method includes providing, using a first attenuator, a first attenuation to the audio recording to produce a first attenuated audio recording. Yet further, the method includes routing the first attenuated audio recording onto an input of a first bus. Further, the method includes providing, using a second attenuator, a second attenuation to the first attenuated audio recording available at an output of the first bus to generate a second attenuated audio recording. Moreover, the method includes routing the second attenuated audio recording onto an input of a second bus. Further, the method includes providing, using a third attenuator, a third attenuation to the second attenuated audio recording available at an output of the second bus to generate a third attenuated audio recording. Yet further, the method includes processing, using a two-stage dual limiter, the third attenuated audio recording to generate a track output, wherein the two-stage dual limiter comprises a first stage and a second stage, wherein the first stage is configured for preventing compression of at least one of predetermined low frequencies and predetermined high frequencies in the third attenuated audio recording, wherein the second stage is configured for preventing transient peaks in the third attenuated audio recording from approaching digital zero. Moreover, the method includes transmitting, using the communication device, the track output to the electronic device.

Further, a system for processing an audio recording for facilitating production of competitively loud mastered audio recording with reduced distortion is disclosed. The system includes a communication device configured for receiving an audio file comprising the audio recording from an electronic device and transmitting a track output to the electronic device. Further, the system includes a first attenuator configured for providing a first attenuation to the audio recording to produce a first attenuated audio recording, wherein the first attenuated audio recording is routed onto an input of a first bus. Yet further, the system includes a second attenuator configured for providing a second attenuation to the first attenuated audio recording available at an output of the first bus to generate a second attenuated audio recording, wherein the second attenuated audio recording is routed onto an input of a second bus. Moreover, the system includes a third attenuator configured for providing a third attenuation to the second attenuated audio recording available at an output of the second bus to generate a third attenuated audio recording. Further, the system includes a two-stage dual limiter configured for processing the third attenuated audio recording to generate the track output, wherein the two-stage dual limiter comprises a first stage and a second stage, wherein the first stage is configured for preventing compression of at least one of predetermined low frequencies and predetermined high frequencies in the third attenuated audio recording, wherein the second stage is configured for preventing transient peaks in the third attenuated audio recording from approaching digital zero.

According to some embodiments, the present disclosure provides a reliable method for producing competitively loud, mastered audio recordings, while leaving plenty of dynamic range to prevent digital distortions. This is achieved while processing in real time by utilizing a series of buses and attenuation stages to prevent the transient peak levels of digital audio track signals from files or streaming audio from clipping on every play through. Additionally, the method allows for controlling louder Sound Pressure Levels (SPLs) without audible distortion than previously thought possible by the scientific community, due to its unique usage of physics inherent to the design. Further, the present disclosure relates to a means of digitally mastering (finalizing) audio recordings for the public to experience and/or purchase. Further, the present disclosure enables users to create the loudest high-resolution mastered digital audio recordings physically possible. Further, unpleasant digital square wave, or “perfect” (linear) distortion which generally encompasses the vast majority of modern processed digital audio recordings marketed to the public, are effectively eliminating. Further, the present disclosure enables users to create mastered digital audio recordings that are competitively as loud or louder than professional recordings released by major record labels, all without clipping digital zero, thereby avoiding digital square wave distortion. This enables users to produce and distribute loud, attention-grabbing music, ADR (Audio Dialog Recordings), and general audio recordings, without creating the harmful digital square wave distortion inherent in most common audio processing procedures.

Both the foregoing summary and the following detailed description provide examples and are explanatory only. Accordingly, the foregoing summary and the following detailed description should not be considered to be restrictive. Further, features or variations may be provided in addition to those set forth herein. For example, embodiments may be directed to various feature combinations and sub-combinations described in the detailed description.

### BRIEF DESCRIPTION OF THE DRAWINGS

The accompanying drawings, which are incorporated in and constitute a part of this disclosure, illustrate various embodiments of the present disclosure. The drawings contain representations of various trademarks and copyrights owned by the Applicants. In addition, the drawings may contain other marks owned by third parties and are being used for illustrative purposes only. All rights to various trademarks and copyrights represented herein, except those belonging to their respective owners, are vested in and the property of the applicants. The applicants retain and reserve all rights in their trademarks and copyrights included herein, and grant permission to reproduce the material only in connection with reproduction of the granted patent and for no other purpose.

Furthermore, the drawings may contain text or captions that may explain certain embodiments of the present disclosure. This text is included for illustrative, non-limiting, explanatory purposes of certain embodiments detailed in the present disclosure.

FIG. 1 is an illustration of a platform consistent with various embodiments of the present disclosure.

FIG. 2 is a block diagram of a system for processing an audio recording for facilitating production of competitively loud mastered audio recording with reduced distortion in accordance with some embodiments.

FIG. 3 is a flowchart of a method for providing first manipulations in accordance with some embodiments.

FIG. 4 is a flowchart of a method for providing second manipulations in accordance with some embodiments.

FIG. 5 is a flowchart for a first stage and a second stage of a two-stage dual limiter in accordance with some embodiments.

FIG. 6 is a flowchart of method for using split-sends for processing an audio recording for facilitating production of competitively loud mastered audio recording with reduced distortion in accordance with some embodiments.

FIG. 7 is a flow chart of a method for processing an audio recording for facilitating production of competitively loud mastered audio recording with reduced distortion in accordance with some embodiments.

FIG. 8 illustrates an exemplary computing system that may be employed to implement processing functionality for various embodiments.

### DETAILED DESCRIPTION OF THE INVENTION

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

Accordingly, while embodiments are described herein in detail in relation to one or more embodiments, it is to be understood that this disclosure is illustrative and exemplary of the present disclosure and are made merely for the purposes of providing a full and enabling disclosure. The detailed disclosure herein of one or more embodiments is not intended, nor is to be construed, to limit the scope of patent protection afforded in any claim of a patent issuing here from, which scope is to be defined by the claims and the equivalents thereof. It is not intended that the scope of patent protection be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection is to be defined by the issued claim(s) rather than the description set forth herein.

Additionally, it is important to note that each term used herein refers to that which an ordinary artisan would understand such term to mean based on the contextual use of such term herein. To the extent that the meaning of a term used herein—as understood by the ordinary artisan based on the contextual use of such term—differs in any way from any particular dictionary definition of such term, it is intended that the meaning of the term as understood by the ordinary artisan should prevail.

Furthermore, it is important to note that, as used herein, “a” and “an” each generally denotes “at least one,” but does not exclude a plurality unless the contextual use dictates otherwise. When used herein to join a list of items, “or” denotes “at least one of the items,” but does not exclude a plurality of items of the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims. The present disclosure contains headers. It should be understood that these headers are used as references and are not to be construed as limiting upon the subjected matter disclosed under the header.

The present disclosure includes many aspects and features. Moreover, while many aspects and features relate to, and are described in, the context of audio processing, embodiments of the present disclosure are not limited to use only in this context.

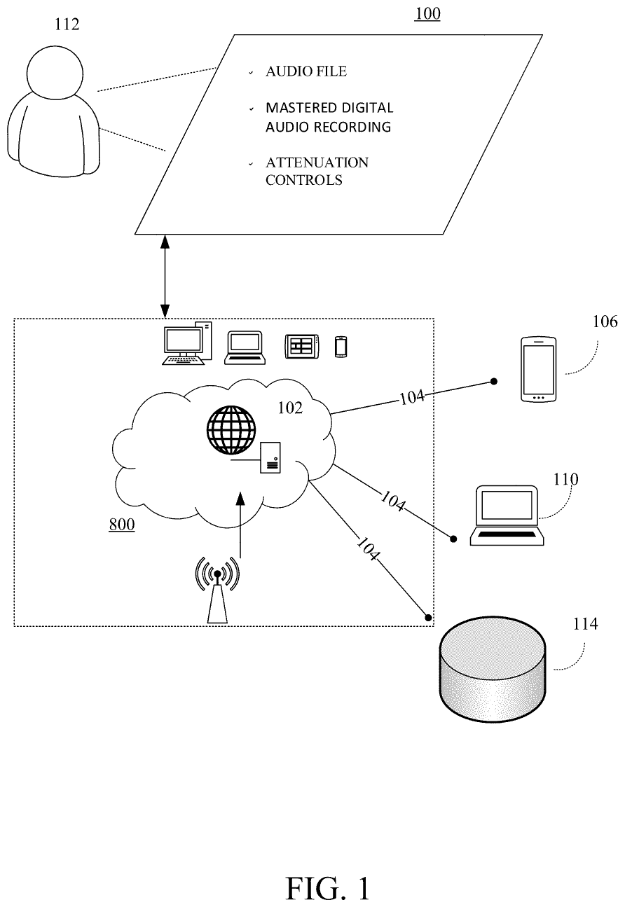

Referring now to figures, FIG. 1 is an illustration of a platform 100 consistent with various embodiments of the present disclosure. By way of non-limiting example, the online platform 100 for processing an audio recording for facilitating production of competitively loud mastered audio recording may be hosted on a centralized server 102, such as, for example, a cloud computing service. The centralized server 102 may communicate with other network entities, such as, for example mobile devices 106 (such as a smartphone, a laptop, a tablet computer etc.), other electronic devices 110 (such as desktop computers, etc.), databases 114 (such as audio databases), via a communication network 104 such as, but not limited to, the Internet. Alternatively, and/or additionally, in some embodiments, the centralized server 102 may communicate with user devices (e.g. mobile devices 106, electronic devices 110) through other communication channels, such as for example, WiFi and a short range communication (e.g. Bluetooth, ZigBee etc.) for uploading (during or after processing) and/or downloading audio files. Further, users of the platform may include one or more relevant parties such as audio engineers, listeners, and system administrators. Accordingly, electronic devices operated by the one or more relevant parties may be in communication with the platform 100.

A user 112, such as the one or more relevant parties, may access platform 100 through a software application. The software application may be embodied as, for example, but not be limited to, a website, a web application, a desktop application, and a mobile application compatible with a computing device 800. The software application may work in stand-alone mode, and as an Application Programming Interface (API). Further, it may be integrated into a web-based or an application-based service that enables users to upload audio files online, allowing fully automated or manually controlled usage of the disclosed method via personal electronic devices (such as mobile devices 106 and electronic devices 110). Further, in some embodiments, one or more user accounts may be maintained corresponding to one or more users of the online platform. Accordingly, a user 112 may be able to upload an input audio file for processing and download an output or processed audio file from the online platform through the user account. Further, in some embodiments, the software application may be integrated into virtually any technology with a digital audio component.

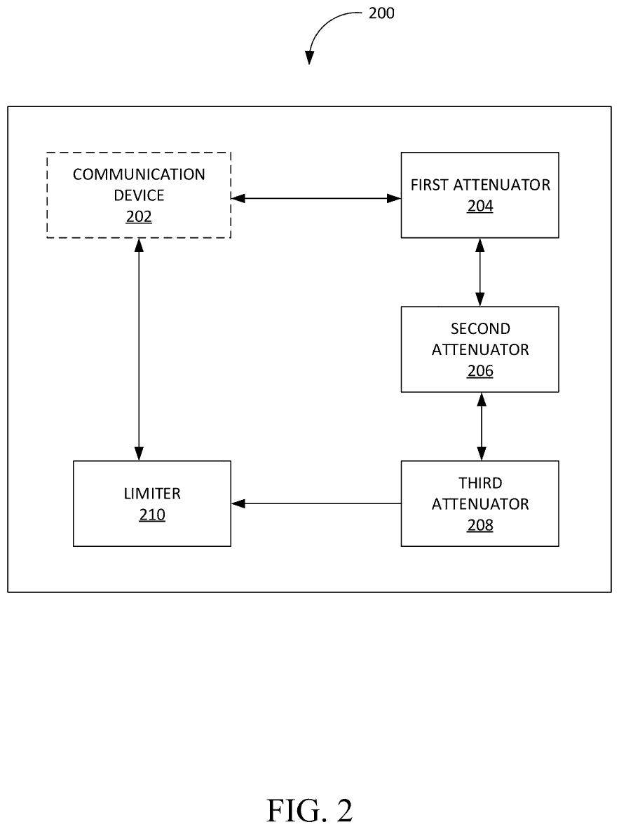

FIG. 2 is a block diagram of a system 200 for processing an audio recording for facilitating production of competitively loud mastered audio recording with reduced distortion in accordance with some embodiments. In some embodiments, the system 200 may be implemented using one or more of analog signal processing devices (or modules) and a Digital Signal Processor (DSP).

The system 200 may include a communication device 202 configured for receiving an audio file including the audio recording from an electronic device (such as the mobile device 106). A user may upload the audio file, or a streaming audio may be routed into an upload track input. Further, the user may upload a variety of file types. In some embodiments, the audio recording may include an unprocessed, mixed digital audio recording. In alternative embodiments, the audio recording may include a mastered digital audio recording.

The system 200 may not utilize traditional faders, instead the system 200 may rely on a series of high-resolution attenuation stages to achieve higher resolution quality (better clarity) than most faders designs would allow. Accordingly, the system 200 may include a first attenuator 204, a second attenuator 206, a third attenuator 208 and a two-stage dual limiter 210. In an embodiment, one or more of the first attenuator 204, the second attenuator 206, the third attenuator 208 and the two-stage dual limiter 210 may be analog or digital devices. In another embodiment, one or more of the first attenuator 204, the second attenuator 206, the third attenuator 208 and the two-stage dual limiter 210 may be implemented using a processing device.

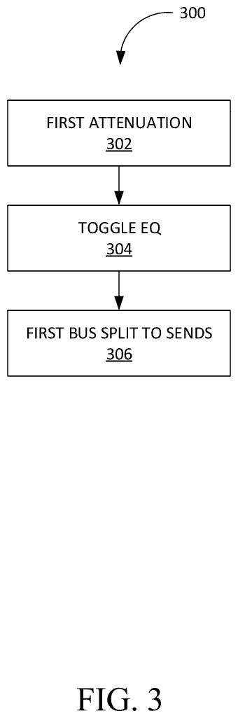

Further, the first attenuator 204 may be configured for providing a first attenuation (or perform first manipulations) to the audio recording to produce a first attenuated audio recording. Thereafter, the first attenuated audio recording may be routed onto an input of a first bus. This is explained in further detail in conjunction with FIG. 3 below.

In further embodiments, the system 200 may also include an additional attenuator configured for providing an additional attenuation to the first attenuated audio recording prior to routing the first attenuated audio recording onto the first bus. The additional attenuation beyond typical settings for the first attenuation may be applied prior to routing the audio recording onto the first bus. Further, the additional attenuation may be provided when a previously mastered digital audio recording is uploaded or streamed into the upload track input. The additional attenuation may compensate for the inherent differences in dynamic range and Sound Pressure Level (SPL) which may be introduced when processing a digital audio recording which has been previously mastered. While the system 200 may greatly improve the resolution quality, it may not fully correct compression artifacts inherent in a digital audio recording which has been over-limited/over-compressed prior to upload. Therefore, it may be best to upload un-mastered digital audio files for the better results.

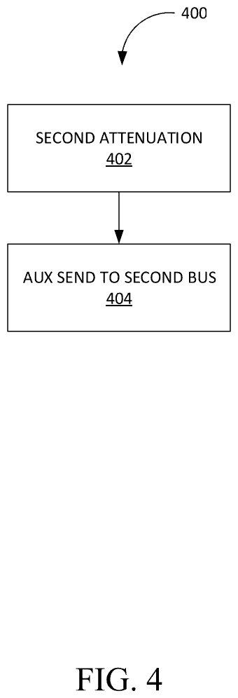

Yet further, the system 200 may include a second attenuator 206 configured for providing a second attenuation (or perform second manipulations) to the first attenuated audio recording available at an output of the first bus to generate a second attenuated audio recording. Further, the second attenuated audio recording may be routed onto an input of a second bus. This is explained in further detail in conjunction with FIG. 4 below.

Further, the system 200 may include a third attenuator 208 configured for providing a third attenuation to the second attenuated audio recording available at an output of the second bus to generate a third attenuated audio recording.

Moreover, the system 200 may include a two-stage dual limiter 210 configured for processing the third attenuated audio recording to generate the track output. Further, the two-stage dual limiter 210 may include a first stage and a second stage. The first stage may be configured for preventing compression of one or more of predetermined low frequencies and predetermined high frequencies in the third attenuated audio recording. The second stage may be configured for preventing transient peaks in the third attenuated audio recording from approaching digital zero. Further, the communication device 202 may be configured for transmitting a track output to the electronic device.

FIG. 3 is a flowchart of a method 300 for providing the first manipulations in accordance with some embodiments. At 302, a first attenuation may be performed either automatically (via algorithm), or manually (controlled by the user 112) to obtain a first attenuated audio recording. Properly attenuating digital audio recordings/streaming audio may prevent wave transient peaks from clipping, while simultaneously preventing lower frequencies from distorting as the low frequency range exponentially increases in power along with the average SPL of the digital audio recording doubling. Without proper attenuation, a massive digital square wave distortion may be introduced in the first attenuated audio recording, which may degrade the resolution quality beyond repair, to the point of possibly damaging any speakers used to monitor the process. Further, the user 112 may attenuate to any desirable volume level below the audio recording's Root Mean Square (RMS)/Peak Volume Levels, with the understanding that the result may prevent unwanted distortions in the end product via a minimized, inaudible loss of resolution quality via attenuation.

In some embodiments, the system 200 may further include an equalizer configured for equalizing the first attenuated audio recording prior to routing the first attenuated audio recording onto the first bus. Accordingly, at 304, the user may have an option of equalizing the first attenuated audio recording. For example, the equalization may occur through a fixed eight-band equalizer. This may ensure that specific frequencies with specific bell and shelf curves are automated or manually set by the user, rather than using traditional equalizer designs to manually sweep through a range of frequencies and Q shapes. The equalizer may have a true bypass design, so the user 112 may be required to toggle the on/off state of the equalizer, either manually or with presets. However, when the equalizer is bypassed it is non-destructive and may not affect the digital audio track signal in any respect. Then, the signal may be routed to the input of the first bus, enabling the user to reroute the digital audio track signal to the input of both the primary track send and clone track send via a split-send of the first bus output at 306.

FIG. 4 is a flowchart of a method 400 for providing the second manipulations in accordance with some embodiments. At 402, a second attenuation may be performed either automatically (via algorithm), or manually (controlled by the user) to obtain a second attenuated audio recording. Then, at 404, the second attenuated audio recording may be routed to the input of the second bus.

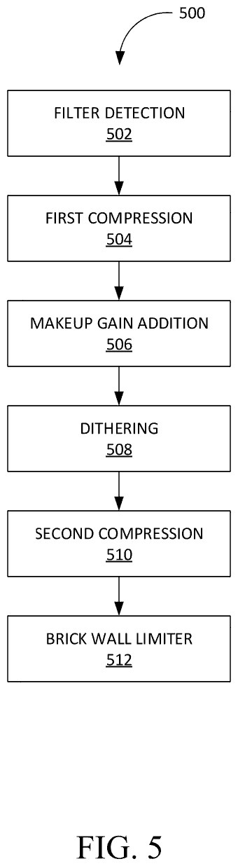

FIG. 5 is a flowchart for the first stage and the second stage of the two-stage dual limiter 210 in accordance with some embodiments. The first stage of the two-stage dual limiter 210 may include filter detection 502, wherein at least one of a Low Pass Filter (LPF) and a High Pass Filter (HPF) may be used to prevent the compression of specific low and/or high frequencies, chosen at the user's discretion either manually, or by preset, prior to a first compression stage 504 to control the merging send track's dynamic range.

Thereafter, at 506, a small amount of makeup gain may be applied if desired to increase resolution quality. Here, minimal percentages of musical, yet barely audible harmonic distortions (mimicking the pleasurable effect of imperfect analog distortions in place of perfect square wave digital distortion) may be added. Further, the two-stage dual limiter 210 may include an amplifier configured for providing a makeup gain to the third attenuated audio recording available at an output of the first stage of the two-stage dual limiter 210.

The second stage of the two-stage dual limiter 210 may include applying dithering (at 508) to lower frequencies chosen at the user's 112 discretion (though typical dithering frequency ranges and more are available). This helps to reduce any audible distortion created by makeup gain via a phenomenon known as auditory masking (as mentioned earlier in this technical data). Further, the two-stage dual limiter 210 may include a dithering device configured for applying dithering to at least one predetermined low frequency in the third attenuated audio recording available at an output of the amplifier.

Moreover, the second stage of the two-stage dual limiter 210 may include a brickwall compressor/limiter. After second compression at 510, the brickwall compressor/limiter 512 may prevent transient peaks from approaching digital zero/clipping, thus preserving the track's dynamic range as the output of the merging track send routes to the input of the print audio track to record a finalized audio file for the user 112 in real time during processing.

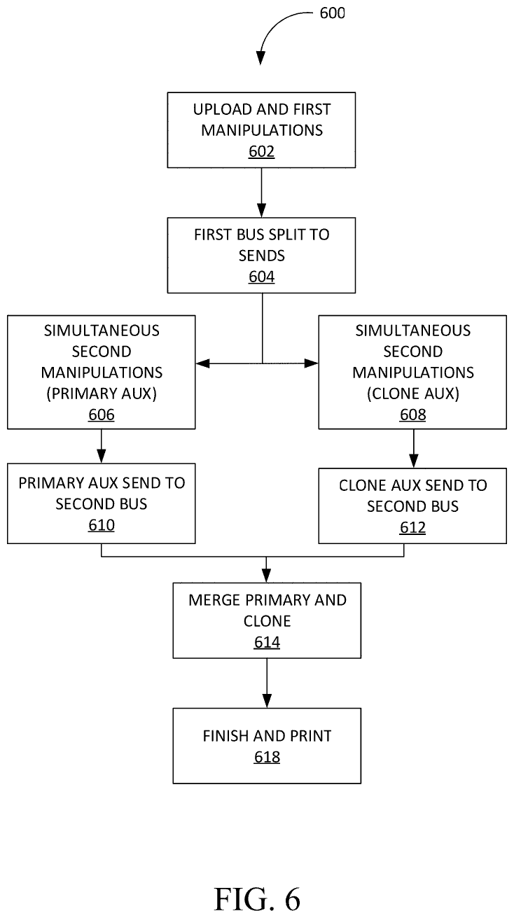

In further embodiments, the first attenuated audio recording may be routed to inputs of each of a primary track send and a clone track send via a split-send of the output of the first bus. Further, a primary SPL associated with the primary track send may be identical to a clone SPL associated with the clone track send. Further, outputs of each of the primary track send and the clone track send may be routed to the input of the second bus. This is explained in further detail in conjunction with FIG. 6 below.

FIG. 6 is a flowchart of method 600 for using split-sends for processing an audio recording for facilitating production of competitively loud mastered audio recording with reduced distortion in accordance with some embodiments. At 602, the audio file may be uploaded, and the first manipulations may be performed on the audio file. Then, at 604, the first bus may split the first attenuated audio recording into a primary track and a clone track. At this stage, the first attenuated audio recording is effectively “cloned” (copied), as two copies of the same signal, equal in SPL and power are both ready to be attenuated simultaneously, in equal measure.

The second manipulations including both the primary track attenuation (at 606), and the clone track attenuation (at 608) are performed in tandem. Therefore, if the user attenuates the primary track via manual control, the clone track is attenuated in the same way, and vice versa. Further, automated settings for attenuation in both tracks work in the same way, always in equal measure, ensuring that the digital audio wave shapes match perfectly together. This may prevent unintentional comb filtering, which may immediately result in undesired phase cancellations if either track attenuation was configured any differently, potentially ruining resolution quality in the event of extreme differences in configuration.

In further embodiments, more than two split-sends may be used to route digital audio track signal to more than just one clone track send, however, in order to prevent phase cancellations, as with the attenuation stages, the user may need to double the amount of split-sends. Accordingly, the user may not use three split-sends including the primary without causing the same sort of phase-related problems, instead the user may have to use four. If more split-sends are request, then after four, the user may go to eight in total, and so on.

Next, the output of the second manipulation of the primary track may be sent to the input of the second bus at 610. Further, the output of the second manipulation of the clone track may be sent to the input of the second bus at 612. Both digital audio track signals may be then combined/merged while being rerouted to the output of the second bus simultaneously into the merging track send (at 614), where a third attenuation stage may be implemented to control the sheer SPL increase generated from wave interference due to merging track signals. Further, the output of the first bus to split sends 604 is processed simultaneously by second manipulations (Primary Aux) 606, and second manipulations (Clone Aux) 608, before being combined by merge primary Clone 614.

Further, whatever resolution quality is lost during the third attenuation, it is instantly masked by the increase in level created by controlled non-linear harmonic distortions from the wave interference. At this point, any such harmonic distortions in the 3rd and 5th harmonic range may be simply musical in nature and may only serve to objectively improve the stereo image and tonal balance of the digital audio track signal.

Additionally, complex harmonic distortions occurring in lower frequencies may also be masked and controlled to such an extent, that a greater sense of spatial depth of field occurs without any perceivable loss of resolution quality (in fact the Fletcher-Munson curves dictate that the opposite has in fact occurred, with the limitations of human hearing creating a sense of greater resolution quality in reaction to the process). Most listeners are likely to describe the experience as “three dimensional”, as the digital audio track signal may sound more “real” and immersive to them in real time as the audio is being processed.

Finally, the output of the merging track send may be routed to the input of the print audio track to record a finalized audio file for the user 112 at 618. This results in a digitally mastered audio recording with both greater dynamic range and clarity of resolution quality than previously possible with older technologies. All while remaining significantly louder in terms of measurable SPL than mastered audio recordings produced by alternative professional means in both the analog and digital realm. Lastly, multiple file types may be exported after processing with ease.

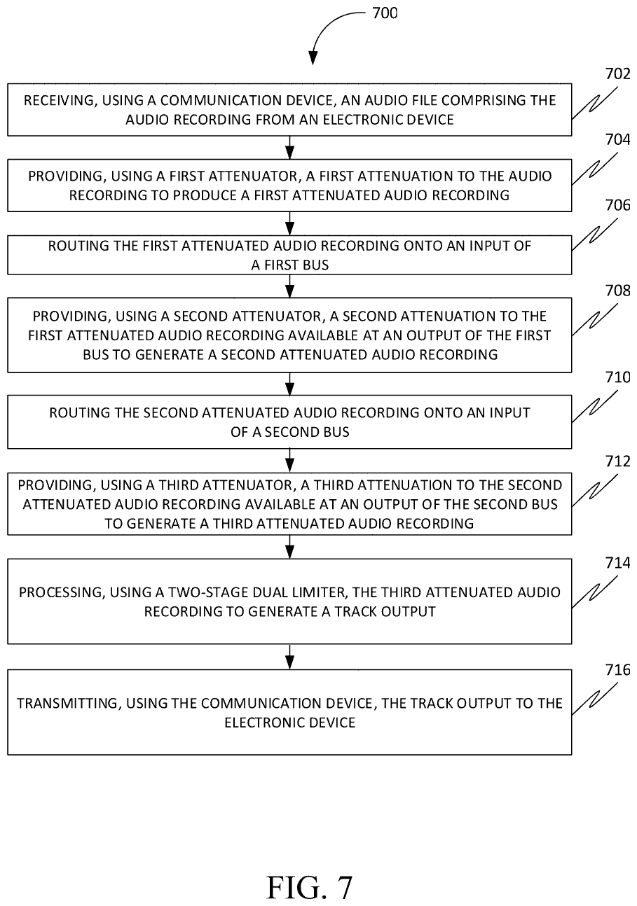

FIG. 7 is a flow chart of a method 700 for processing an audio recording for facilitating production of competitively loud mastered audio recording with reduced distortion in accordance with some embodiments. At 702, the method 700 may include receiving, using a communication device (such as the communication device 202), an audio file including the audio recording from an electronic device. In some embodiments, the audio recording may include an unprocessed, mixed digital audio recording. In some embodiments, the audio recording may include a mastered digital audio recording.

Further, at 704, the method 700 may include providing, using a first attenuator (such as the first attenuator 204), a first attenuation to the audio recording to produce a first attenuated audio recording. Further, the method 700 may include routing the first attenuated audio recording onto an input of a first bus. In some embodiments, the method 700 may further include providing, using an additional attenuator, an additional attenuation to the first attenuated audio recording prior to routing the first attenuated audio recording onto the first bus. In further embodiments, the method 700 may include equalizing, using an equalizer, the first attenuated audio recording prior to routing the first attenuated audio recording onto the first bus.

Further, the method 700 may include providing, using a second attenuator (such as the second attenuator 206), a second attenuation to the first attenuated audio recording available at an output of the first bus to generate a second attenuated audio recording. Further, the method 700 may include routing the second attenuated audio recording onto an input of a second bus. Further, the method 700 may include providing, using a third attenuator (such as the third attenuator 208), a third attenuation to the second attenuated audio recording available at an output of the second bus to generate a third attenuated audio recording. Further, the method 700 may include processing, using a two-stage dual limiter (such as the two-stage dual limiter 210), the third attenuated audio recording to generate a track output.

Further, the two-stage dual limiter may include a first stage and a second stage. Further, the first stage may be configured for preventing compression of one or more of predetermined low frequencies and predetermined high frequencies in the third attenuated audio recording. In some embodiments, the first stage of the two-stage dual limiter may include one or more of a Low Pass Filter (LPF) and a High Pass Filter (HPF). In further embodiments, the method 700 may include providing, using an amplifier, a makeup gain to the third attenuated audio recording available at an output of the first stage of the two-stage dual limiter. In further embodiments, the method 700 may include applying, using a dithering device, dithering to at least one predetermined low frequency in the third attenuated audio recording available at an output of the amplifier.

Further, the second stage may be configured for preventing transient peaks in the third attenuated audio recording from approaching digital zero. In some embodiments, the second stage of the two-stage dual limiter may include a brickwall compressor. Further, the method 700 may include transmitting, using the communication device, the track output to the electronic device.

In some embodiments, the method 700 may further include routing the first attenuated audio recording to inputs of each of a primary track send and a clone track send via a split-send of the output of the first bus. Further, a primary Sound Pressure Level (SPL) associated with the primary track send may be identical to a clone SPL associated with the clone track send. Further, outputs of each of the primary track send and the clone track send may be routed to the input of the second bus.

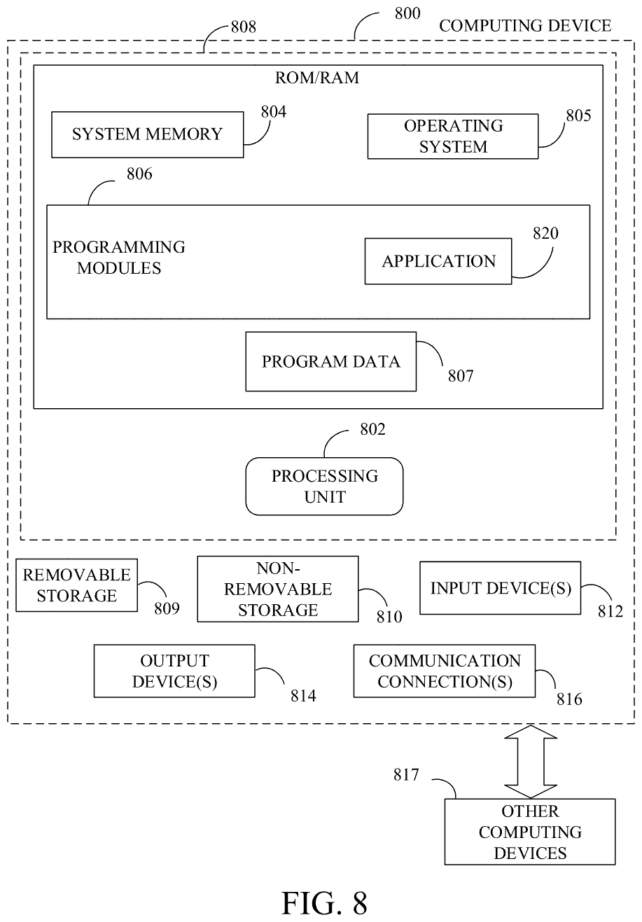

FIG. 8 is a block diagram of a system including computing device 800. Consistent with an embodiment of the disclosure, the aforementioned memory storage and processing unit may be implemented in a computing device, such as computing device 800 of FIG. 8. Any suitable combination of hardware, software, or firmware may be used to implement the memory storage and processing unit. For example, the memory storage and processing unit may be implemented with computing device 800 or any of other computing devices 818, in combination with computing device 800. The aforementioned system, device, and processors are examples and other systems, devices, and processors may comprise the aforementioned memory storage and processing unit, consistent with embodiments of the disclosure.

With reference to FIG. 8, a system consistent with an embodiment of the disclosure may include a computing device or cloud service, such as computing device 800. In a basic configuration, computing device 800 may include at least one processing unit 802 and a system memory 804. Depending on the configuration and type of computing device, system memory 804 may comprise, but is not limited to, volatile (e.g. random-access memory (RAM)), non-volatile (e.g. read-only memory (ROM)), flash memory, or any combination. System memory 804 may include operating system 805, one or more programming modules 806, and may include a program data 807. Operating system 805, for example, may be suitable for controlling computing device 800's operation. In one embodiment, programming modules 806 may include a digital signal processing module, an attenuation module, a low pass filtering module, a high pass filtering module, a limiter module, dithering module, a brickwall compressor module, an equalizer module and an amplification module. Accordingly, in some embodiments, the programming modules 806 may be implemented using one or more of software and hardware. For example, in an instance, the programming modules 806 may be implemented as modules of a Digital Signal Processor (DSP). Further, in another instance, multiple types of completely DSP chip powered and/or analog physical hardware unit designs may be used. Further, the implementation of the programming modules could also be a combination of mostly DSP modules with some analog modules/processing as well. Further, in some embodiments, as long as the dithering module is implemented via a DSP chip, technically the rest of the modules may be analog modules. Accordingly, stress testing may be performed to determine which components would be best for each unit's physical size limitations.

Furthermore, embodiments of the disclosure may be practiced in conjunction with a graphics library, other operating systems, or any other application program and is not limited to any particular application or system. This basic configuration is illustrated in FIG. 8 by those components within a dashed line 808.

Computing device 800 may have additional features or functionality. For example, computing device 800 may also include additional data storage devices (removable and/or non-removable) such as, for example, magnetic disks, optical disks, or tape. Such additional storage is illustrated in FIG. 8 by a removable storage 809 and a non-removable storage 810. Computer storage media may include volatile and nonvolatile, removable and non-removable media implemented in any method or technology for storage of information, such as computer-readable instructions, data structures, program modules, or other data. System memory 804, removable storage 809, and non-removable storage 810 are all computer storage media examples (i.e., memory storage.) Computer storage media may include, but is not limited to, RAM, ROM, electrically erasable read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store information and which can be accessed by computing device 800. Any such computer storage media may be part of device 800. Computing device 800 may also have input device(s) 812 such as a keyboard, a mouse, a pen, a sound input device, a touch input device, etc. Output device(s) 814 such as a display, speakers, a printer, etc. may also be included. The aforementioned devices are examples and others may be used.

Computing device 800 may also contain a communication connection 816 that may allow device 800 to communicate with other computing devices 818, such as over a network in a distributed computing environment, for example, an intranet or the Internet. Communication connection 816 is one example of communication media. Communication media may typically be embodied by computer readable instructions, data structures, program modules, or other data in a modulated data signal, such as a carrier wave or other transport mechanism, and includes any information delivery media. The term “modulated data signal” may describe a signal that has one or more characteristics set or changed in such a manner as to encode information in the signal. By way of example, and not limitation, communication media may include wired media such as a wired network or direct-wired connection, and wireless media such as acoustic, radio frequency (RF), infrared, and other wireless media. The term computer readable media as used herein may include both storage media and communication media.

As stated above, a number of program modules and data files may be stored in system memory 804, including operating system 805. While executing on processing unit 802, programming modules 806 (e.g., application 820) may perform processes including, for example, one or more stages of methods, algorithms, systems, applications, servers, databases as described above. The aforementioned process is an example, and processing unit 802 may perform other processes.

Generally, consistent with embodiments of the disclosure, program modules may include routines, programs, components, data structures, and other types of structures that may perform particular tasks or that may implement particular abstract data types. Moreover, embodiments of the disclosure may be practiced with other computer system configurations, including hand-held devices, multiprocessor systems, microprocessor-based or programmable consumer electronics, minicomputers, mainframe computers, and the like. Embodiments of the disclosure may also be practiced in distributed computing environments where tasks are performed by remote processing devices that are linked through a communications network. In a distributed computing environment, program modules may be located in both local and remote memory storage devices.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to mechanical, optical, fluidic, and quantum technologies. In addition, embodiments of the disclosure may be practiced within a general-purpose computer or in any other circuits or systems.

Embodiments of the disclosure, for example, may be implemented as a computer process (method), a computing system, or as an article of manufacture, such as a computer program product or computer readable media. The computer program product may be a computer storage media readable by a computer system and encoding a computer program of instructions for executing a computer process. The computer program product may also be a propagated signal on a carrier readable by a computing system and encoding a computer program of instructions for executing a computer process. Accordingly, the present disclosure may be embodied in hardware and/or in software (including firmware, resident software, micro-code, etc.). In other words, embodiments of the present disclosure may take the form of a computer program product on a computer-usable or computer-readable storage medium having computer-usable or computer-readable program code embodied in the medium for use by or in connection with an instruction execution system. A computer-usable or computer-readable medium may be any medium that can contain, store, communicate, propagate, or transport the program for use by or in connection with the instruction execution system, apparatus, or device.

The computer-usable or computer-readable medium may be, for example, but not limited to, an electronic, magnetic, optical, electromagnetic, infrared, or semiconductor system, apparatus, device, or propagation medium. More specific computer-readable medium examples (a non-exhaustive list), the computer-readable medium may include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may, in fact, be executed substantially concurrently or the blocks may sometimes be executed in the reverse order, depending upon the functionality/acts involved.

While certain embodiments of the disclosure have been described, other embodiments may exist. Furthermore, although embodiments of the present disclosure have been described as being associated with data stored in memory and other storage mediums, data can also be stored on or read from other types of computer-readable media, such as secondary storage devices, like hard disks, solid state storage (e.g., USB drive), or a CD-ROM, a carrier wave from the Internet, or other forms of RAM or ROM. Further, the disclosed methods' stages may be modified in any manner, including by reordering stages and/or inserting or deleting stages, without departing from the disclosure.

Although the invention has been explained in relation to its preferred embodiment, it is to be understood that many other possible modifications and variations can be made without departing from the spirit and scope of the invention.

What is claimed is:

1. A method of processing an audio recording for facilitating production of competitively loud mastered audio recording with reduced distortion, the method comprising:
receiving, using a communication device, an audio file comprising the audio recording from an electronic device;
providing, using a first attenuator, a first attenuation to the audio recording to produce a first attenuated audio recording;
routing the first attenuated audio recording onto an input of a first bus;
providing, using a second attenuator, a second attenuation to the first attenuated audio recording available at an output of the first bus to generate a second attenuated audio recording;
routing the second attenuated audio recording onto an input of a second bus;
providing, using a third attenuator, a third attenuation to the second attenuated audio recording available at an output of the second bus to generate a third attenuated audio recording;
processing, using a two-stage dual limiter, the third attenuated audio recording to generate a track output, wherein the two-stage dual limiter comprises a first stage and a second stage, wherein the first stage is configured for preventing compression of at least one of predetermined low frequencies and predetermined high frequencies in the third attenuated audio recording, wherein the second stage is configured for preventing transient peaks in the third attenuated audio recording from approaching digital zero; and
transmitting, using the communication device, the track output to the electronic device.

2. The method of claim 1, wherein the audio recording comprises an unprocessed, mixed digital audio recording.

3. The method of claim 1, wherein the audio recording comprises a mastered digital audio recording.

4. The method of claim 3 further comprising providing, using an additional attenuator, an additional attenuation to the first attenuated audio recording prior to routing the first attenuated audio recording onto the first bus.

5. The method of claim 1, wherein the first stage of the two-stage dual limiter comprises at least one of a Low Pass Filter (LPF) and a High Pass Filter (HPF).

6. The method of claim 1 further comprising providing, using an amplifier, a makeup gain to the third attenuated audio recording available at an output of the first stage of the two-stage dual limiter.

7. The method of claim 6 further comprising applying, using a dithering device, dithering to at least one predetermined low frequency in the third attenuated audio recording available at an output of the amplifier.

8. The method of claim 1, wherein the second stage of the two-stage dual limiter comprises a brickwall compressor.

9. The method of claim 1 further comprising equalizing, using an equalizer, the first attenuated audio recording prior to routing the first attenuated audio recording onto the first bus.

10. The method of claim 1 further comprising routing the first attenuated audio recording to inputs of each of a primary track send and a clone track send via a split-send of the output of the first bus, wherein a primary Sound Pressure Level (SPL) associated with the primary track send is identical to a clone SPL associated with the clone track send, wherein outputs of each of the primary track send and the clone track send are routed to the input of the second bus.

11. The method of claim 10, wherein routing of each of the primary track send and the clone track send to the input of the second bus causes wave interference and results in increased SPL.

12. The method of claim 1, wherein providing at least one of the first attenuation, the second attenuation and the third attenuation enables production of a competitively loud mastered audio recording without clipping digital zero, thereby avoiding digital square wave distortion.

13. The method of claim 1, wherein at least one of the first attenuation, the second attenuation and the third attenuation may correspond to a volume level below at least one of the Root Mean Square (RMS) value and a Peak Volume Level.

14. The method of claim 4, wherein the additional attenuation is configured to compensate for inherent differences in dynamic range and Sound Pressure Level encountered when processing the mastered digital audio recording.

15. The method of claim 7, wherein the dithering is configured to reduce an audible distortion created by the makeup gain.

16. A system for processing an audio recording for facilitating production of competitively loud mastered audio recording with reduced distortion, the system comprising:
a communication device configured for:
receiving an audio file comprising the audio recording from an electronic device; and
transmitting a track output to the electronic device;
a first attenuator configured for providing a first attenuation to the audio recording to produce a first attenuated audio recording, wherein the first attenuated audio recording is routed onto an input of a first bus;
a second attenuator configured for providing a second attenuation to the first attenuated audio recording available at an output of the first bus to generate a second attenuated audio recording, wherein the second attenuated audio recording is routed onto an input of a second bus;
a third attenuator configured for providing a third attenuation to the second attenuated audio recording available at an output of the second bus to generate a third attenuated audio recording; and
a two-stage dual limiter configured for processing the third attenuated audio recording to generate the track output, wherein the two-stage dual limiter comprises a first stage and a second stage, wherein the first stage is configured for preventing compression of at least one of predetermined low frequencies and predetermined high frequencies in the third attenuated audio recording, wherein the second stage is configured for preventing transient peaks in the third attenuated audio recording from approaching digital zero.

17. The system of claim 16, wherein the audio recording comprises an unprocessed, mixed digital audio recording.

18. The system of claim 16, wherein the audio recording comprises a mastered digital audio recording.

19. The system of claim 18 further comprising an additional attenuator configured for providing an additional attenuation to the first attenuated audio recording prior to routing the first attenuated audio recording onto the first bus.

20. The system of claim 16, wherein the first stage of the two-stage dual limiter comprises at least one of a Low Pass Filter (LPF) and a High Pass Filter (HPF).

21. The system of claim 16 further comprising an amplifier configure for providing a makeup gain to the third attenuated audio recording available at an output of the first stage of the two-stage dual limiter.

22. The system of claim 16 further comprising a dithering device configured for applying dithering to at least one predetermined low frequency in the third attenuated audio recording available at an output of the amplifier.

23. The system of claim 16, wherein the second stage of the two-stage dual limiter comprises a brickwall compressor.

24. The system of claim 16 further comprising an equalizer configured for equalizing the first attenuated audio recording prior to routing the first attenuated audio recording onto the first bus.

25. The system of claim 16, wherein the first attenuated audio recording is routed to inputs of each of a primary track send and a clone track send via a split-send of the output of the first bus, wherein a primary Sound Pressure Level (SPL) associated with the primary track send is identical to a clone SPL associated with the clone track send, wherein outputs of each of the primary track send and the clone track send are routed to the input of the second bus.

26. The system of claim 25, wherein routing of each of the primary track send and the clone track send to the input of the second bus causes wave interference and results in increased SPL.

27. The system of claim 16, wherein providing at least one of the first attenuation, the second attenuation and the third attenuation enables production of a competitively loud mastered audio recording without clipping digital zero, thereby avoiding digital square wave distortion.

28. The system of claim 16, wherein at least one of the first attenuation, the second attenuation and the third attenuation may correspond to a volume level below at least one of the Root Mean Square (RMS) value and a Peak Volume Level.

29. The system of claim 19, wherein the additional attenuation is configured to compensate for inherent differences in dynamic range and Sound Pressure Level encountered when processing the mastered digital audio recording.

30. The system of claim 22, wherein the dithering is configured to reduce an audible distortion created by the makeup gain.
